(19) United States
(12) Patent Application Publication
(10) Pub. No.: US 2016/0163939 A1
(43) Pub. Date: Jun. 9, 2016

(54) OPTOELECTRONIC SEMICONDUCTOR CHIP, SEMICONDUCTOR COMPONENT AND METHOD OF PRODUCING OPTOELECTRONIC SEMICONDUCTOR CHIPS

(71) Applicant: OSRAM OPTO SEMICONDUCTORS GMBH, Regensburg (DE)

(72) Inventors: Ralph Wagner, Neutraubling (DE); Thomas Veit, Mintraching (DE); Björn Hoxhold, Sinzing (DE); Philipp Schlosser, Regensburg (DE)

(21) Appl. No.: 14/906,724

(22) PCT Filed: Jul. 17, 2014
(86) PCT No.: PCT/EP2014/065445

§ 371 Date: Jan. 21, 2016

(30) Foreign Application Priority Data
Jul. 25, 2013 (DE) 102013107971.7

(51) Int. Cl. H01L 33/62; H01L 31/02; H01L 31/0203; H01L 33/52

(52) U.S. Cl. CPC H01L 33/62; H01L 33/52; H01L 31/02005; H01L 31/0203

(57) ABSTRACT

An optoelectronic semiconductor chip includes a carrier, a semiconductor body having an active region that generates and/or receives radiation, and an insulation layer wherein the semiconductor body is fastened on the carrier with a connecting layer; the carrier extends in a vertical direction between a first main surface facing toward the semiconductor body, and a second main surface facing away from the semiconductor body, and a lateral surface connects the first main surface and the second main surface to one another; a first region of the lateral surface of the carrier has an indentation; a second region of the lateral surface runs in the vertical direction between the indentation and the second main surface; the insulation layer at least partially covers each of the semiconductor body and the first region; and the second region is free of the insulation layer.

### TECHNICAL FIELD

This disclosure relates to an optoelectronic semiconductor chip, a semiconductor component having such a semiconductor chip, and a method of producing optoelectronic semiconductor chips.

### BACKGROUND

In semiconductor chips, for the electrical contacting of which a contact track is led beyond the edge of the semiconductor chip, the risk exists of an electrical short-circuit of the semiconductor chip in the region of the edge.

It could therefore be helpful to provide an optoelectronic semiconductor chip in which the risk of an electrical short-circuit during the electrical contacting is reduced. Furthermore, it could be helpful to provide reliably electrically contactable semiconductor chips that may be produced in a simple and cost-effective manner.

### SUMMARY

We provide an optoelectronic semiconductor chip including a carrier, a semiconductor body having an active region that generates and/or receives radiation, and an insulation layer wherein the semiconductor body is fastened on the carrier with a connecting layer; the carrier extends in a vertical direction between a first main surface facing toward the semiconductor body, and a second main surface facing away from the semiconductor body, and a lateral surface connects the first main surface and the second main surface to one another; a first region of the lateral surface of the carrier has an indentation; a second region of the lateral surface runs in the vertical direction between the indentation and the second main surface; the insulation layer at least partially covers each of the semiconductor body and the first region; and the second region is free of the insulation layer.

We further provide a semiconductor component including the semiconductor chip and a molded body, wherein the molded body is molded onto the semiconductor chip and at least regionally covers each of the first region and the second region of the lateral surface of the carrier; and the semiconductor component has a contact track leading from a front side of the semiconductor chip and facing away from the second main surface of the carrier via the first region of the carrier to a front side of the molded body.

We yet further provide a method of producing a plurality of semiconductor chips including:
a) providing a composite having a semiconductor layer sequence having an active region that generates and/or receives radiation and is divided into a plurality of semiconductor bodies, and having a carrier composite on which the semiconductor layer sequence is arranged;
b) forming trenched depressions running at least regionally between adjacent semiconductor bodies and extending into the carrier composite;
c) forming an insulation layer that at least regionally covers each of the semiconductor layer sequence and the lateral surfaces of the trenched depressions; and
d) singulating the composite into the plurality of semiconductor chips, wherein the singulation takes place by singulation cuts running at least regionally along the trenched depressions.

Our semiconductor chip may have a semiconductor body having an active region that generates and/or receives radiation.

### BRIEF DESCRIPTION OF THE DRAWINGS

FIG. 1 shows an example of a semiconductor chip in a schematic sectional view.

FIGS. 2A and 2B show an example of a semiconductor component in a schematic sectional view (FIG. 2A) and a schematic top view (FIG. 2B).

FIGS. 3A to 3F show a first example of a method of producing semiconductor chips on the basis of intermediate steps in a schematic sectional view (FIGS. 3A to 3D) and in a top view (FIGS. 3E and 3F).

FIGS. 4A to 4C show a second example of a method of producing semiconductor chips in a sectional view (FIG. 4A) and in a top view (FIGS. 4B and 4C).

For example, the active region is arranged between a first semiconductor layer of a first conduction type and a second semiconductor layer of a second conduction type, which is different from the first conduction type. For example, the semiconductor body, in particular the active region, contains a III-V compound semiconductor material.

The semiconductor chip may have a carrier. The carrier extends in a vertical direction between a first main surface facing toward the semiconductor body, and a second main surface facing away from the semiconductor body. A lateral surface connects the first main surface and the second main surface to one another. The lateral surface thus delimits the carrier in the lateral direction. The carrier is in particular different from a growth substrate for the epitaxial deposition of the semiconductor layers of the semiconductor body. For example, the carrier contains a semiconductor material such as silicon, germanium, or gallium arsenide.

The semiconductor body may be fastened using a connecting layer on the carrier. In particular, a material bond is formed between the semiconductor body and the carrier by the connecting layer. In a material bond, the connection partners, which are in particular pre-manufactured, are held together by atomic and/or molecular forces. In particular an electrically conductive connecting layer is suitable for the connecting layer. For example, the connecting layer contains a solder or an electrically conductive adhesive.

The lateral surface of the carrier may have a first region, wherein the first region has an indentation. In a top view of the semiconductor chip, the carrier has a smaller cross-sectional area at the height of the first region than in a second region, which is different from the first region. The second region adjoins the first region in the vertical direction in particular.

The second region runs in particular in the vertical direction between the indentation and the second main surface. For example, the indentation adjoins the first main surface of the carrier.

A vertical extension of the indentation is, for example, 5% to 70%, in particular 10% to 60% of the vertical extension of the carrier.

The semiconductor chip may have an insulation layer. The insulation layer runs at least regionally on the side of the semiconductor body facing away from the carrier. In particular, the insulation layer, in a top view of the semiconductor chip, covers all regions of the semiconductor chip not provided for external electrical contacting. In other words, for example, a contact surface for the external electrical contacting of the semiconductor chip is free of the insulation layer. In particular, the insulation layer is formed as a coherent layer formed in a single deposition step, and which at least regionally covers both the first region of the carrier and also the semiconductor body, and in particular directly adjoins each of them.

The insulation layer may at least partially cover each of the semiconductor body and the first region of the lateral surface. In particular, the insulation layer completely covers the first region of the lateral surface. In the region of the indentation, the carrier material is thus not exposed in the lateral direction, but rather is covered by the material of the insulation layer.

The second region may be free of the insulation layer. The second region of the lateral surface arises during production of the semiconductor chips, in particular during singulation of the semiconductor chips from a composite. In the second region of the lateral surface, the semiconductor chip can therefore have traces of a singulation step, for example, traces of a material removal. The material removal can be performed by coherent radiation, chemically, and/or mechanically.

The semiconductor chip may have a carrier and a semiconductor body having an active region that generates and/or receives radiation, wherein the semiconductor body is fastened using a connecting layer on the carrier. The carrier extends in a vertical direction between a first main surface facing toward the semiconductor body, and a second main surface facing away from the semiconductor body, wherein a lateral surface connects the first main surface and the second main surface to one another. A first region of the lateral surface of the carrier has an indentation. A second region of the lateral surface runs in the vertical direction between the indentation and the second main surface. The semiconductor chip has an insulation layer at least partially covering each of the semiconductor body and the first region. The second region is free of the insulation layer.

The insulation layer thus covers the carrier not only on the first main surface, but rather also at least regionally, in particular completely, in the region of the indentation. In the region of the indentation, the lateral surface of the carrier is thus not exposed, but rather is covered by the insulation layer. The risk of an electrical short-circuit during the external electrical contacting of the semiconductor chip, for example, via a contact track guided beyond the edge of the semiconductor chip, which is formed in the form of a coating, for example, is thus reduced. Furthermore, an insulating layer provided in addition to the insulation layer and is only applied after the singulation into semiconductor chips, can be omitted.

The carrier may be electrically conductive. Electrical contacting of the semiconductor chip can take place through the carrier, in particular via the material of the carrier itself.

The insulation layer may completely cover a part of the connecting layer protruding laterally beyond the semiconductor body. In other words, the connecting layer is not exposed at any point of the semiconductor chip.

Our semiconductor component may have a semiconductor chip and a molded body. The semiconductor chip can in particular have at least one or more features of the above-described semiconductor chip. The molded body is molded onto the semiconductor chip and at least regionally covers each of the first region and the second region of the lateral surface of the carrier. In particular, the molding compound can completely cover the second region. A front side of the semiconductor chip, which is used in particular as a radiation transmission surface, is free of material of the molded body, for example.

The semiconductor component may have a contact track led from a front side of the semiconductor chip and facing away from the second main surface of the carrier via the first region of the carrier to a front side of the molded body. The semiconductor component can have one or more electrical contacts on the front side of the molded body and/or on the rear side of the molded body for the external electrical contacting.

The contact track does not directly adjoin the carrier at any point. The risk of an electrical short-circuit between the contact track and the carrier is thus avoided.

The method of producing a plurality of semiconductor chips may provide a composite having a semiconductor layer sequence and a carrier composite. The semiconductor layer sequence comprises in particular an active region that generates and/or receives radiation, and is divided into a plurality of semiconductor bodies, for example. The semiconductor layer sequence is arranged on the carrier composite and fastened by a material bond to the carrier composite, for example.

The carrier composite has a front side facing toward the semiconductor layer sequence and a rear side facing away from the semiconductor layer sequence.

The method may comprise formation of trenched depressions running at least regionally between adjacent semiconductor bodies and extending into the carrier composite. The trenched depressions do not extend in the vertical direction completely through the carrier composite, however. For example, the trenched depressions are formed by coherent radiation, in particular by a laser in pulsed operation, for example, using a pulse duration in the picosecond or nanosecond range. Alternatively or additionally, for example, a chemical method can be used, for example, wet chemical or dry chemical etching, or a mechanical method, for example, a grinding method or a sawing method. A wafer saw is suitable, for example.

Formation of the trenched depressions can be performed, for example, between adjacent semiconductor bodies parallel to a first direction. In addition, formation of the trenched depressions can take place in a second direction running diagonally or perpendicularly in relation to the first direction.

The method may comprise formation of an insulation layer which at least regionally covers each of the semiconductor layer sequence and the lateral surfaces of the trenched depressions. Formation of the insulation layer is carried out, for example, by a CVD method (chemical vapor deposition) or a PVD method (physical vapor deposition). An ALD method (atomic layer deposition) is suitable in particular for deposition of the insulation layer. A conformal coverage of the composite, i.e., a coating following the topography of the composite can be achieved in a particularly reliable manner by an ALD method. Reliable insulation of edges to be molded over can thus already be achieved with very thin layers.

The method may comprise singulation of the composite into the plurality of semiconductor chips, wherein the singulation takes place by singulation cuts running at least regionally along the trenched depressions.

The term “singulation cuts” does not imply any type of restriction with respect to the type of the production in this case. The singulation cuts can in particular be formed mechanically, for example, by cleavage, fracture, or sawing, chemically, for example, by wet chemical or dry chemical etching, or by coherent radiation. In the regions in which the singulation cuts run along the trenched depressions, the singulation cuts can be formed completely inside the trenched depressions, in particular in a top view of the composite.

A front side of the carrier composite facing toward the semiconductor layer sequence may be free of metallic material in the region of the trenched depressions during singulation. During singulation, no metallic material applied to the front side is thus severed.

A rear side of the carrier composite facing away from the semiconductor layer sequence may be free of metallic material during singulation. No metallic material is thus provided on the rear side of the carrier composite.

The carrier composite may be thinned, in particular after formation of the trenched depressions. The structural height of the semiconductor chips to be produced can be reduced by the thinning. At the same time, the carrier composite can mechanically stabilize the semiconductor layer sequence particularly reliably before the thinning.

The singulation cuts running along the trenched depressions during singulation may have a lesser width than the trenched depressions. Formation of the singulation cuts within the trenched depressions is thus simplified. Furthermore, the required spacing between adjacent semiconductor bodies can thus be minimized.

An electrical contact surface may be formed on each of the semiconductor bodies and the singulation cuts running along the trenched depressions between adjacent semiconductor bodies are each formed so that a center line of the singulation cuts is more remote from the closest contact surface of the adjacent semiconductor bodies than a center line of the associated trenched depression. The contact surfaces are in particular not arranged centrally on the respective semiconductor bodies so that the contact surface of a semiconductor chip adjoining on one side of the trenched depression is closer to the trenched depression than the contact surface of the semiconductor chip adjoining on the other side of the trenched depression.

The carrier may be singulated during singulation from the side opposite to the trenched depressions, in particular from the rear side of the carrier composite. Positioning of the singulation cuts in relation to the trenched depressions can take place by optical recognition of the trenched depressions through the carrier composite. In particular, a high level of optical contrast can be achieved by metal-free trenched depressions and metallic material arranged therebetween.

Alternatively, the carrier composite can also be singulated from the side on which the trenched depressions are also formed, in particular from the front side of the carrier composite.

A material modification by laser radiation which is complete or only regional in the vertical direction, for example, a material removal, may take place in the carrier composite during singulation. A laser ablation method is suitable for complete material removal, for example, by a laser in pulsed operation having pulse durations in the nanosecond or picosecond range, for example.

In only regional material modification, the singulation can be mechanically induced along fractures defined by the material modification. In particular, the material modification can induce a mechanical tension in the material, which defines the fractures. For example, a stealth dicing method is suitable for this purpose.

A chemical material removal may take place in the carrier composite during singulation. In particular a dry chemical method is suitable for this purpose, for example, a plasma separation method.

The described method is particularly suitable for producing an above-described semiconductor chip. Features mentioned in conjunction with the semiconductor chip can therefore also be used for the method and vice versa.

Further features and advantageous properties result from the following description of the examples in conjunction with the figures.

Identical, equivalent, or identically-acting elements are provided with identical reference signs in the figures.

The figures and the size ratios among one another of the elements illustrated in the figures are not shown to scale. Rather, individual elements and in particular layer thicknesses can be shown exaggeratedly large for better illustration ability and/or for better comprehension.

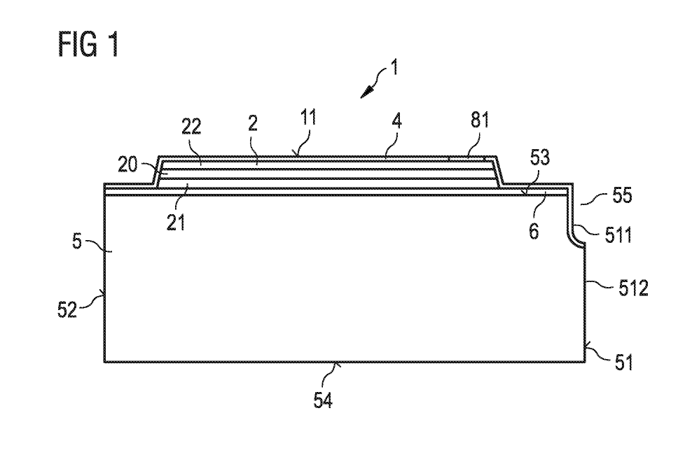

An example of a semiconductor chip 1 is shown in a schematic sectional view in FIG. 1. The semiconductor chip 1 comprises a semiconductor body 2 and a carrier 5. The semiconductor body 2 comprises an active region 20 that generates radiation and/or receives radiation and is arranged between a first semiconductor layer 21 of a first conduction type (for example, p-conductive) and a second semiconductor layer 22 of a second conduction type (for example, n-conductive).

A III-V compound semiconductor material is suitable in particular for the semiconductor layer sequence. III-V compound semiconductor materials are particularly suitable for generating radiation in the ultraviolet (Alₓ In_{y} Ga_{1-x-y} N) via the visible (Alₓ In_{y} Ga_{1-x-y} N, in particular for blue to green radiation, or Alₓ In_{y} Ga_{1-x-y} P, in particular for yellow to red radiation) up into the infrared (Alₓ In_{y} Ga_{1-x-y} As) spectral range. For this purpose, 0≦x≦1, 0≦y≦1, and x+y≦1, in particular with x≠1, y≠1, x≠0, and/or y≠0. High internal quantum efficiencies when generating radiation can furthermore be achieved using III-V compound semiconductor materials, in particular from the mentioned material systems.

The semiconductor body 2 is fastened on the carrier by a connecting layer 6, for example, a solder layer or an electrically conductive adhesive layer. The carrier 5 is used for mechanical stabilization of the semiconductor body 2. A growth substrate for the deposition, which is in particular epitaxial, of the semiconductor layers of the semiconductor body is no longer required for this purpose and is therefore removed. A semiconductor chip, in which the growth substrate is removed, is also referred to as a thin-film semiconductor chip.

Notwithstanding this, however, it is also possible that the carrier 5 itself is the growth substrate for the semiconductor layers of the semiconductor body 2. In this case, a connecting layer between semiconductor body and carrier is not necessary.

The carrier 5 extends in a vertical direction between a first main surface 53 facing toward the semiconductor body 2, and a second main surface 54. A lateral surface 51, which delimits the semiconductor body in a lateral direction, i.e., in a direction running parallel to a main extension plane of the semiconductor layers of the semiconductor body, runs between the first main surface and the second main surface. A semiconductor material is suitable in particular for the carrier, for example, silicon, germanium, or gallium arsenide. Another material is alternatively also possible, for example, a metal.

The lateral surface 51 has a first region 511 and a second region 512 adjoining the first region. In the first region, the carrier 5 has an indentation 55. The lateral surface 51 does not run in the vertical direction, in contrast to conventional semiconductor chips, completely in one plane between the first main surface 53 and the second main surface. Rather, the lateral extension of the carrier is intentionally reduced in the first region, i.e., in the region of the indentation. The lateral extension of the indentation is preferably at least 0.5 μm and at most 20 μm.

The second region runs in the vertical direction between the first region 511 and the second main surface 54. The indentation 55 adjoins the first main surface 53 of the carrier 5. In a top view of the semiconductor chip 1, the carrier has a smaller cross-sectional area in the region of the indentation than in the second region 512.

A further lateral surface 52 of the carrier is free of an indentation. However, the carrier can also have such an indentation on more than one lateral surface, for example, on two opposing lateral surfaces and/or on two adjoining lateral surfaces or also on all lateral surfaces.

The semiconductor chip has a contact surface 81 for the electrical contacting of the semiconductor chip on the side facing away from the second main surface 54. In the example shown, the contact surface overlaps with the semiconductor body 2 in a top view of the semiconductor chip. Notwithstanding this, however, the contact surface can also be arranged laterally spaced apart from the semiconductor body 2 on the carrier 5.

The semiconductor chip 1 furthermore comprises an insulation layer 4. The insulation layer is formed on a front side 11 of the semiconductor chip. The insulation layer 4 covers the semiconductor body 2, in particular its lateral surfaces. Furthermore, the insulation layer covers the regions of the connecting layer 6 protruding laterally beyond the semiconductor body 2 and the first main surface 53 of the carrier. Furthermore, the insulation layer 4 covers the first region 511 of the lateral surface 51. The carrier 5 is thus not exposed in the first region 511, but rather is in particular completely covered by the insulation layer. The risk of a short-circuit via the carrier during the electrical contacting of the semiconductor chip is thus avoided. An insulation layer provided in addition to the insulation layer 4, which covers the lateral surfaces of the semiconductor body 2, is thus not necessary.

The second region 512 is free of the insulation layer. The carrier 5 is thus exposed in the second region. An oxide, for example, aluminum oxide (such as Al₂O₃) or silicon oxide or a nitride such as silicon nitride, is suitable as a material for the insulation layer, for example.

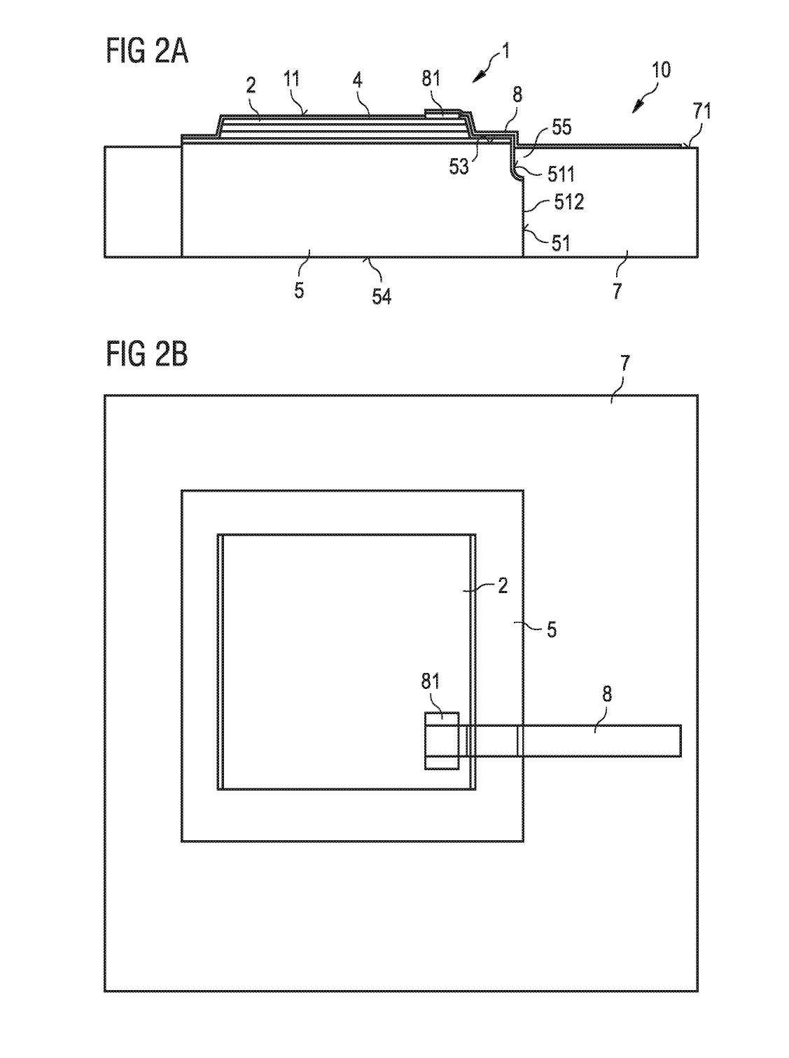

An example of a semiconductor component is schematically shown in FIGS. 2A and 2B. In this example, the semiconductor chip 1 is as described in conjunction with FIG. 1. The semiconductor component 10 furthermore comprises a molded body 7. During production of the semiconductor component, a molding compound for the molded body 7 is molded onto the semiconductor chip 1, in particular onto the carrier 5. For example, a casting method is suitable for formation of the molded body.

A casting method is understood in general as a method, using which a molding compound can be formed according to a predefined shape, for example, by casting (molding), injection molding, or transfer molding.

The molded body 7 adjoins the semiconductor chip 1 in particular in the first region 511 and in the second region 512 of the lateral surface 51. The insulation layer 4 is formed in the first region between the carrier 5 and the molded body 7. In the second region, the molded body adjoins the carrier.

For example, a plastic, for example, a silicone is suitable for the molded body. The molded body can furthermore be admixed with reflective particles, for example, TiO2 particles.

From the front side 11 of the semiconductor chip, a contact track 8 is led from the contact surface 81 of the semiconductor chip via an edge of the semiconductor chip in the lateral direction beyond the semiconductor chip onto a front side 71 of the molded body 7. The semiconductor component 10 can have, for example, two front contacts for the external electrical contacting or two rear contacts or one front contact and one rear contact. The contacts are not explicitly shown for simplified illustration.

It is ensured by the insulation layer 4 that the contact track 8 does not directly adjoin the carrier 5 at any point. The risk of an electrical short-circuit between the contact track and the carrier, in particular on the lateral surface of the carrier, is thus avoided.

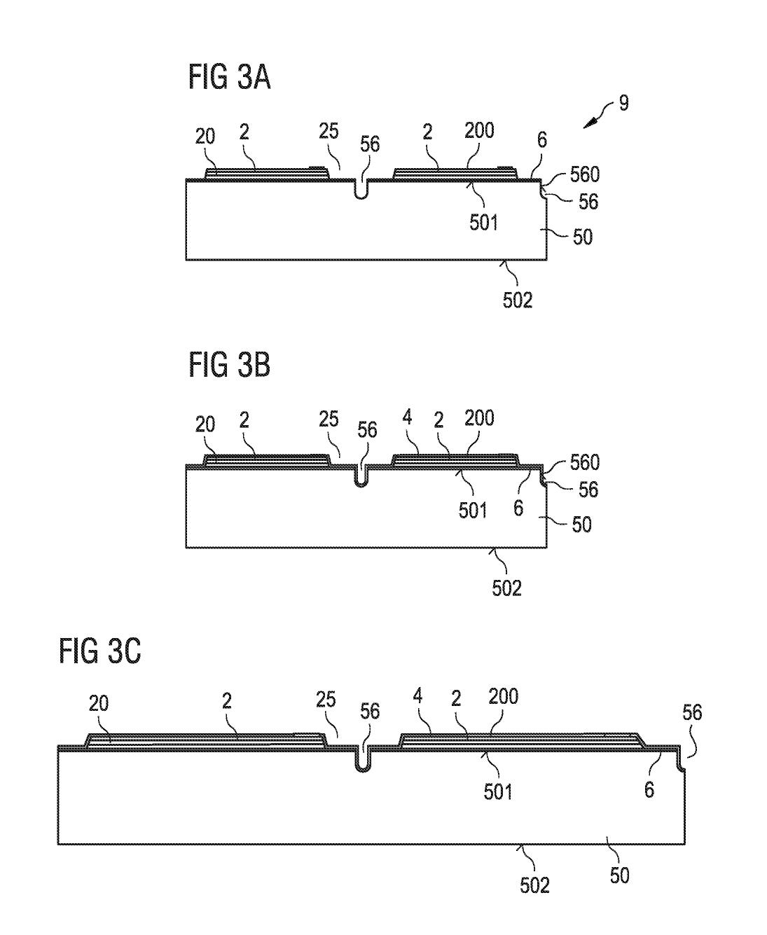

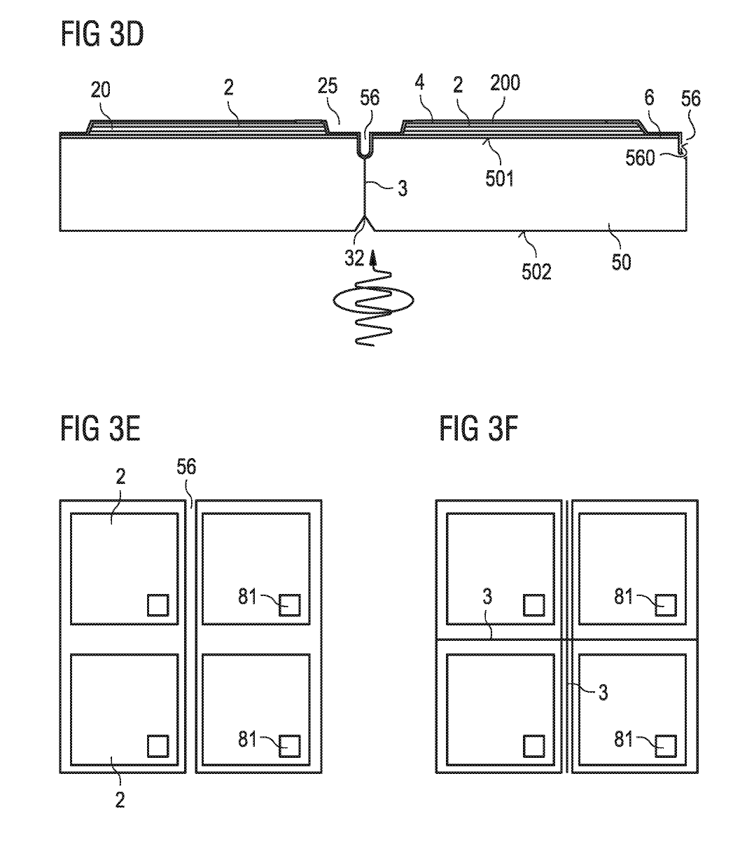

FIGS. 3A to 3F show a first example of a method of producing semiconductor chips. In each case, a detail, from which two semiconductor chips originate during the production, is shown in a sectional view in the illustration.

As FIG. 3A shows, a composite 9 is provided, which has a carrier composite 50 and a semiconductor layer sequence 200. The carrier composite extends in the vertical direction between a front side 501 facing toward the semiconductor layer sequence 200, and an opposing rear side 502. The individual carriers of the semiconductor chips are formed from the carrier composite in the later singulation step. In the example shown, the semiconductor layer sequence 200 is fastened using a connecting layer 6 on the carrier composite 50. Notwithstanding this, the carrier composite can also be formed by a growth substrate for the semiconductor layer sequence 200.

The semiconductor layer sequence 200 is divided by mesa trenches 25 into semiconductor bodies 2 spaced apart from one another. A trenched depression 56 is formed in the carrier composite from the front side. The trenched depression extends in the vertical direction into the carrier composite, but does not completely sever the carrier composite in the vertical direction. In a top view of the composite, the trenched depressions 56 run between adjacent semiconductor bodies 2.

Formation of the trenched depressions can be carried out, for example, by laser ablation, for example, by a pulsed laser having a pulse duration in the picosecond or nanosecond range. Alternatively, the trenched depressions can also be produced by a chemical method, for example, a dry chemical etching method. Furthermore, a mechanical method such as a grinding method or a sawing method can also be used. A wafer saw is suitable, for example.

Before formation of the trenched depressions 56, the connecting layer 6 can extend continuously over the carrier composite. Structuring of the connecting layer is thus performed in this case during formation of the trenched depression. A pulsed laser, in particular having a pulse duration in the picosecond range, is particularly suitable for this purpose as a result of the low material selectivity during removal.

As shown in FIG. 3E, it is already sufficient if the trenched depressions only run parallel to one another along a first direction. No formation of trenched depressions thus takes place between semiconductor bodies arranged adjacent to one another along this direction. Notwithstanding this, however, it is also possible to additionally form the trenched depressions along a second direction running diagonally or perpendicularly in relation to the first direction.

After formation of the trenched depressions, as shown in FIG. 3B, an insulation layer 4 is applied to the front side of the composite. The insulation layer in particular also covers the trenched depressions and directly adjoins the carrier composite 50 in the region of the trenched depressions. The insulation layer is furthermore formed so that it covers all regions of the front side of the composite 9 not provided for electrical contacting of the later semiconductor chips. Only the contact surface 81 remains free of the insulation layer 4. In particular an ALD method is suitable for formation of the insulation layer. However, another deposition method, for example, a CVD method, for example, vapor deposition or a PVD method, for example, sputtering can also be used.

The carrier composite 50 is subsequently thinned from the rear side 502. After thinning, the vertical extension of the trenched depressions 56 is preferably 10% to 70%, particularly preferably 20% to 50% of the thickness of the carrier composite 50 (FIG. 3C).

The composite 9 is subsequently singulated by a stealth dicing method (FIG. 3D). For this purpose, first, a fracture 32 is generated by radiation-induced material modification so that the irradiated material is under mechanical tension.

A fracture of the carrier is subsequently mechanically induced. The singulation cut 3 thus resulting runs along the first direction in the region of each of the trenched depressions 56. Singulation is performed in this case along the first direction and the second direction running perpendicularly thereto (FIG. 3F).

For an alignment of the singulation cuts 3 in relation to the trenched depressions 56, the position of the trenched depressions can be ascertained through the carrier by optical methods, for example, by a camera sensitive in the infrared spectral range. In this case, the trenched depressions 56 are expressed in the metal-free embodiment thereof, while metallic layers are provided between the trenched depressions, for example, a solder layer as the connecting layer 6.

The rear side of the carrier composite 50 is also free of metallic material. In this way, a view through the carrier for the alignment of the singulation cuts 3 in relation to the trenched depressions 56 is simplified.

The second region 512 of the lateral surface 51 of the carrier 5 of the semiconductor chip that arises during singulation, arises due to the singulation cut 3. In this region, the lateral surface is free of material of the insulation layer 4. Depending on the type of formation of the singulation cut, the second region can at least regionally have traces of the singulation cut.

Indentations 55 in the first region 511 of the lateral surface are formed by the trenched depressions 56. These first regions are completely covered by the insulation layer 4. In contrast, the second region 512 only arises after formation of the insulation layer and is therefore free of material of the insulation layer.

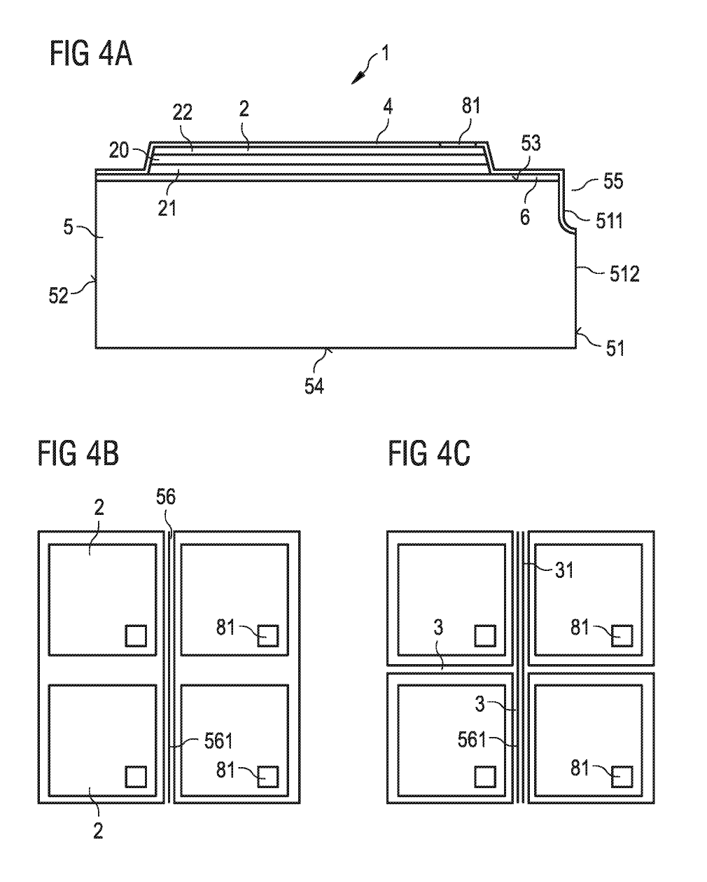

A second example of a method is shown in FIGS. 4A to 4C. In this second example, provision of the composite, formation of the trenched depressions and formation of the insulation layer 4, as well as thinning of the carrier composite can take place as described in conjunction with FIGS. 3A to 3C.

In contrast to the first example, singulation takes place in this example as shown in FIG. 4A from the front side of the composite 9. For example, singulation takes place by laser ablation using a pulsed laser having pulse durations in the picosecond or nanosecond range. The singulation cut 3 can have a width comparable to the trenched depression 56 in this case.

Formation of the singulation cut in relation to the associated trenched depression 56 preferably takes place such that a center line 31 of the singulation cut 3 runs parallel and offset to a center line 561 of the trenched depression in a top view of the composite 9. In particular, the singulation cut is offset such that the center line 31 of the singulation cut 3 has a greater distance to the closest contact surface 81 than the center line of the trenched depression 56. In this manner, it is ensured that the carrier 5 of the singulated semiconductor chips arising during singulation of the carrier composite 50 has an indentation 55 on at least one lateral surface 51 covered with the insulation layer 4.

FIGS. 4B and 4C show the position of the trenched depressions 56 and the singulation cuts 3 in a top view of the composite 9. While the trenched depressions are only formed along the first direction, the singulation takes place along the first direction and additionally perpendicularly thereto along the second direction.

During the described singulation from the front side of the composite 9, the rear side 502 of the carrier composite 50 can also be provided with a metallization, notwithstanding the described example, for example, for the external electrical contacting of the semiconductor chip 2.

Notwithstanding the above-described examples, singulation can also take place by a chemical method, for example, by a plasma method. Singulation can also take place in this case, as described in conjunction with FIGS. 3A to 3F, from the rear side or as described in conjunction with FIGS. 4A to 4C, from the front side of the composite. In singulation from the front side, the insulation layer can be removed before formation of the singulation cut in the region of the singulation cut to be executed, i.e., at the bottom of the trenched depressions 56. This can take place, for example, by laser ablation, for example, by a pulsed laser having pulse durations in the picosecond range.

This application claims priority of DE 10 2013 107 971.7, the content of the disclosure of which is hereby incorporated by reference.

Our chips, components and methods are not restricted by the description on the basis of the examples. Rather, the disclosure comprises every novel feature and every combination of features including in particular every combination of features in the appended claims, even if the feature or combination itself is not explicitly specified in the claims or examples.

1.-16. (canceled)

17. An optoelectronic semiconductor chip comprising a carrier, a semiconductor body having an active region that generates and/or receives radiation, and an insulation layer wherein
the semiconductor body is fastened on the carrier with a connecting layer;
the carrier extends in a vertical direction between a first main surface facing toward the semiconductor body, and a second main surface facing away from the semiconductor body, and a lateral surface connects the first main surface and the second main surface to one another;
a first region of the lateral surface of the carrier has an indentation;
a second region of the lateral surface runs in the vertical direction between the indentation and the second main surface;
the insulation layer at least partially covers each of the semiconductor body and the first region; and
the second region is free of the insulation layer.

18. The semiconductor chip according to claim 17, wherein the carrier is electrically conductive.

19. The semiconductor chip according to claim 17, wherein the insulation layer completely covers a part of the connecting layer protruding laterally beyond the semiconductor body.

20. The semiconductor chip according to claim 17, wherein a vertical extension of the indentation is 10% to 70% of the vertical extension of the carrier.

21. A semiconductor component comprising the semiconductor chip according to claim 17 and a molded body, wherein
the molded body is molded onto the semiconductor chip and at least regionally covers each of the first region and the second region of the lateral surface of the carrier; and
the semiconductor component has a contact track, leading from a front side of the semiconductor chip and facing away from the second main surface of the carrier via the first region of the carrier to a front side of the molded body.

22. A method of producing a plurality of semiconductor chips comprising:
a) providing a composite having a semiconductor layer sequence having an active region that generates and/or receives radiation and is divided into a plurality of semiconductor bodies, and having a carrier composite on which the semiconductor layer sequence is arranged;
b) forming trenched depressions running at least regionally between adjacent semiconductor bodies and extending into the carrier composite;
c) forming an insulation layer that at least regionally covers each of the semiconductor layer sequence and the lateral surfaces of the trenched depressions; and
d) singulating the composite into the plurality of semiconductor chips, wherein the singulation takes place by singulation cuts running at least regionally along the trenched depressions.

23. The method according to claim 22, wherein a front side of the carrier composite facing toward the semiconductor layer sequence is free of metallic material in step d) in the region of the trenched depressions.

24. The method according to claim 22, wherein a rear side of the carrier composite facing away from the semiconductor layer sequence is free of metallic material in step d).

25. The method according to claim 22, wherein the carrier composite is thinned after step b).

26. The method according to claim 22, wherein the singulation cuts running along the trenched depressions in step d) have a lesser width than the trenched depressions.

27. The method according to claim 22, wherein an electrical contact surface is formed on each of the semiconductor bodies and the singulation cuts running along the trenched depressions between adjacent semiconductor bodies are each formed so that a center line of the singulation cuts is more remote from the closest contact surface of the adjacent semiconductor bodies than a center line of the associated trenched depression.

28. The method according to claim 22, wherein the carrier composite is singulated in step d) from the side opposite to the trenched depressions.

29. The method according to claim 28, wherein positioning of the singulation cuts in relation to the trenched depressions takes place by optical recognition of the trenched depressions through the carrier composite.

30. The method according to claim 22, wherein a material modification by laser radiation which is complete or only regional in the vertical direction takes place in the carrier composite in step d).

31. The method according to claim 22, wherein a chemical material removal takes place in the carrier composite in step d).

32. The method according to claim 22, wherein the trenched depressions are formed in step b) by coherent radiation and/or chemically and/or mechanically.

33. The method according to claim 22, wherein the singulation cuts are formed completely inside the trenched depressions and an electrical contact surface is formed on each of the semiconductor bodies and the singulation cuts running along the trenched depressions between adjacent semiconductor bodies are each formed so that a center line of the singulation cuts is more remote from the closest contact surface of the adjacent semiconductor bodies than a center line of the associated trenched depression.

34. A semiconductor component comprising an optoelectronic semiconductor chip and a molded body, wherein
the optoelectronic semiconductor chip has a carrier and a semiconductor body having an active region that generates and/or receives radiation;
the semiconductor body is fastened using a connecting layer on the carrier;
the carrier extends in a vertical direction between a first main surface facing toward the semiconductor body, and a second main surface facing away from the semiconductor body, wherein a lateral surface connects the first main surface and the second main surface to one another;
a first region of the lateral surface of the carrier has an indentation;
a second region of the lateral surface runs in the vertical direction between the indentation and the second main surface;
the semiconductor chip insulation layer at least partially covers each of the semiconductor body and the first region;
the second region is free of the insulation layer;
the molded body is molded onto the semiconductor chip and at least regionally covers each of the first region and the second region of the lateral surface of the carrier; and
the semiconductor component has a contact track leading from a front side of the semiconductor chip facing away from the second main surface of the carrier via the first region of the carrier to a front side of the molded body.
